(19) United States
(12) Patent Application Publication
(10) Pub. No.: US 2026/0023096 A1
(43) Pub. Date: Jan. 22, 2026

(54) Locking Ring Member

(71) Applicant: KABUSHIKI KAISHA NIHON MICRONICS, Tokyo (JP)

(72) Inventors: Takao YASUTA, TOKYO (JP); Takayuki NARUMI, TOKYO (JP)

(73) Assignee: KABUSHIKI KAISHA NIHON MICRONICS, Tokyo (JP)

(21) Appl. No.: 19/269,335

(22) Filed: Jul. 15, 2025

(30) Foreign Application Priority Data
Jul. 19, 2024 (JP) 2024-116146

(51) Int. Cl. G01R 1/04; G01R 31/28

(52) U.S. Cl. CPC G01R 1/04; G01R 31/2863

(57) ABSTRACT

A plate-shaped locking ring member is used to mount a probe substrate on a top plate of a prober included in a test apparatus used to test a device under test. The locking ring member includes a ring shape part, and projection portions protruding outward from a peripheral edge part of the ring shape part, arranged apart from each other along the peripheral edge part. The ring shape part included in the locking ring member has one surface facing the probe substrate, and another surface opposite to the one surface. An adhesive applied at a plurality of points separately from each other bonds the one surface facing the probe substrate of the ring shape part included in the locking ring member to one surface of the probe substrate. The locking ring member has a concave portion in each of a plurality of points subjected to application of the adhesive.

### CROSS-REFERENCE TO RELATED APPLICATIONS

The present application claims priority under 35 U.S.C. § 119 to Japanese Patent Application No. 2024-116146, filed on Jul. 19, 2024. The contents of this application are incorporated herein by reference in their entirety.

### TECHNICAL FIELD

The present disclosure relates to a locking ring member, and is applicable to a locking ring member for probe substrate mounting to be used in an electrical connector which is used to conduct electrical testing, for example, energization testing of a semiconductor integrated circuit formed on a semiconductor wafer.

### BACKGROUND ART

For example, a plurality of semiconductor integrated circuits are formed on a semiconductor, and the semiconductor integrated circuits respectively require electrical testing to check whether or not the semiconductor integrated circuits respectively have electrical characteristics according to specifications.

In the electrical testing, a probe card having a plurality of probes is mounted on the test head of test apparatus, and the electrode terminals of the semiconductor integrated circuits and the corresponding probes are connected electrically. The test apparatus then provides a test signal to the electrode terminals of the semiconductor integrated circuits via the probes, the semiconductor integrated circuits then output electrical signals corresponding to the test signal. The electrical signals are provided to the test apparatus via the probes. This allows the test apparatus to test whether or not the semiconductor integrated circuits have the electrical characteristics according to the specifications, on the basis of the electrical signals received from the semiconductor integrated circuits.

For example, PatentC Document 1 discloses the assembling method of the probe card. Herein, a method of mounting a mounting member on a probe is simply described with reference to Paten Document 1. Conventionally, the method includes, in order to fix a support member for mounting a probe substrate on a card holder, applying a general-purpose adhesive to the upper surface of the edge part of the probe substrate made of ceramic, and mounting a locking ring member on the probe substrate. The method further includes leaving the above state until the general-purpose adhesive cures, screwing and fixing a bolt into a female threaded hole of the mounted locking ring member, and thereafter setting the probe substrate with the locking ring member mounted, on an open part of the card holder.

### CITATION LIST

### Patent Literature

[Patent Document 1] Japanese Patent Application Laid-Open Publication No. 2014-89121

### SUMMARY OF INVENTION

### Technical Problem

In certain cases where a semiconductor integrated circuit is used, it is used in high-temperature environments, for example, higher than 125° C., and accordingly a probe card is also required to have equivalent durability to that of the semiconductor integrated circuit in high-temperature environments.

Such a general-purpose adhesive (elastic adhesive) used conventionally, having insufficient durability in high-temperature environments, may crack, or the bonded interface between the support member and the probe substrate may separate.

To address the problem described above, a high-temperature resistant, high-strength adhesive may be used, instead of such an elastic adhesive.

However, in some cases of a probe substrate made of ceramic and a locking ring member bonded to each other by applying a high-temperature resistant, high-strength adhesive to the portion (the entire periphery of the ring) between the upper surface of the edge part of the ceramic probe substrate and the locking ring member, and placed in high-temperature environments, the probe substrate develops cracks (fissures) due to a difference in coefficients of thermal expansion between the material of the probe substrate and the material (metal) of the locking ring member.

In the case above, the probe substrate made of ceramic is fixed. Also, in the case of another electronic member formed by combining a component having an electrical connection system represented by a probe card and a different component, similar problems exist.

In view of the problems described above, the purpose of the present disclosure is to provide a locking ring member for probe substrate mounting exhibiting a lower risk of damage due to a difference in thermal expansion between a ceramic member and a metal member even in high-temperature environments.

### Solution to Problem

In order to solve the above problems, the present disclosure provides a locking ring member for probe substrate mounting having a plate shape, used to mount a probe substrate on a card holder provided to a top plate of a prober included in a test apparatus used to test a device under test. 1. The locking ring member includes a ring shape part having substantially the same size as a surface of the probe substrate, and projection portions protruding outward from a peripheral edge part of the ring shape part, arranged apart from each other along the peripheral edge part. The locking ring member has one surface facing the probe substrate, and another surface opposite to the one surface. An adhesive applied at a plurality of points separately from each other bonds the one surface facing the probe substrate of the ring shape part included in the locking ring member to one surface of the probe substrate. 2. The ring shape part of the locking ring member has a concave portion in each of a plurality of points subjected to application of the adhesive.

### Advantageous Effects of Invention

The present disclosure prevents the damage of the probe substrate made of ceramic and the locking ring member made of metal even in high-temperature environments.

### BRIEF DESCRIPTION OF DRAWINGS

FIG. 1 is a side view of test apparatus according to an embodiment.

FIG. 2 shows a locking ring member according to the embodiment.

FIG. 3 is a flowchart indicating a method of mounting the locking ring member on a probe substrate according to the embodiment.

FIG. 4 shows the probe substrate before and after the mounting of the locking ring member according to the embodiment.

FIG. 5 shows a cross-sectional view of the bonded interface between the locking ring member and the probe substrate member according to the embodiment.

### DESCRIPTION OF EMBODIMENTS

### A. Major Embodiment

The embodiment of the locking ring member for probe substrate mounting according to the present disclosure is described below with reference to the drawings.

In the present embodiment, the locking ring member according to the present disclosure is used in the probe substrate which establishes electrical connection between test apparatus and a device under test by making probes (electrical contacts) contact with a plurality of electrode terminals of the device under test.

### A-1. Test Apparatus

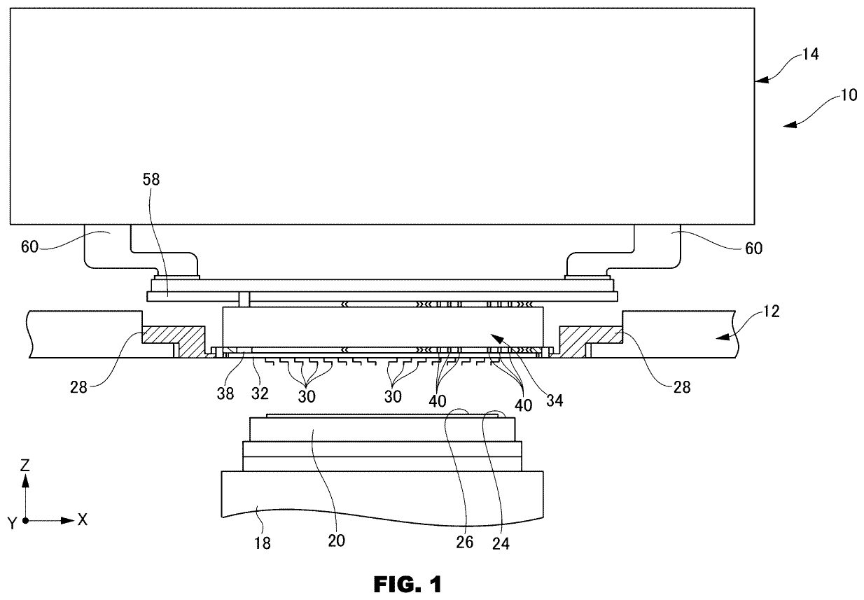

The components of a test apparatus 10 are described with reference to FIG. 1. The test apparatus 10 includes a prober 12, a test head 14, and device-under-test transport mechanism. The prober 12 includes a test stage 18 as a “stage” on which a device under test is placed, a chuck 20, and a probe substrate 32.

The probe substrate 32 is mounted via a card holder 28 provided to the top plate of the prober 12, above a placement surface 24 of the chuck 20. The test head 14, which is electrically connected to the probe substrate 32, is provided further above the probe substrate 32.

The test apparatus 10 conducts testing by moving the chuck 20 closer to a probe 30 arranged on the probe substrate 32 until an electrode of a device under test 26 placed on the placement surface 24 becomes in contact with the corresponding probe 30 arranged on the probe substrate 32, and then energizing the device under test 26 in the above state.

The components provided between the probe substrate and the test head are detailed next with reference to FIG. 1. There are the probe substrate 32, an interposer 34, a wiring circuit substrate 58, and a connection cable 60, between the probe substrate and the test head.

The probe substrate 32 has a disk shape (circle) in the present embodiment, and is configured as a multi layered wiring substrate including a ceramic substrate and a thin film wiring layer. The probe substrate 32 includes a plurality of the probes 30 on the surface (one surface) facing the placement surface 24 of the chuck 20. The probe substrate 32 further includes a plurality of anchors 38 serving as “first reference bodies” on the surface (another surface) facing the interposer 34. Each of the anchors 38 has a columnar shape.

The probe substrate 32 includes a plurality of internal wiring paths not shown. One end of each wiring path is connected to each probe 30, while the other end is connected to each connection land (not shown) provided on the surface (another surface) facing the interposer 34 so as to correspond to the arrangement of connection terminals 40 of the interposer 34 on the XY plane.

There is a locking ring member 80 to be described later, provided on the outer peripheral part of the probe substrate 32. The locking ring member 80 is configured to be locked to the card holder 28.

### A-2. Locking Ring Member

The locking ring member 80, which is mounted on the probe substrate 32 (for example, a substrate member 321 made of ceramic), is described next.

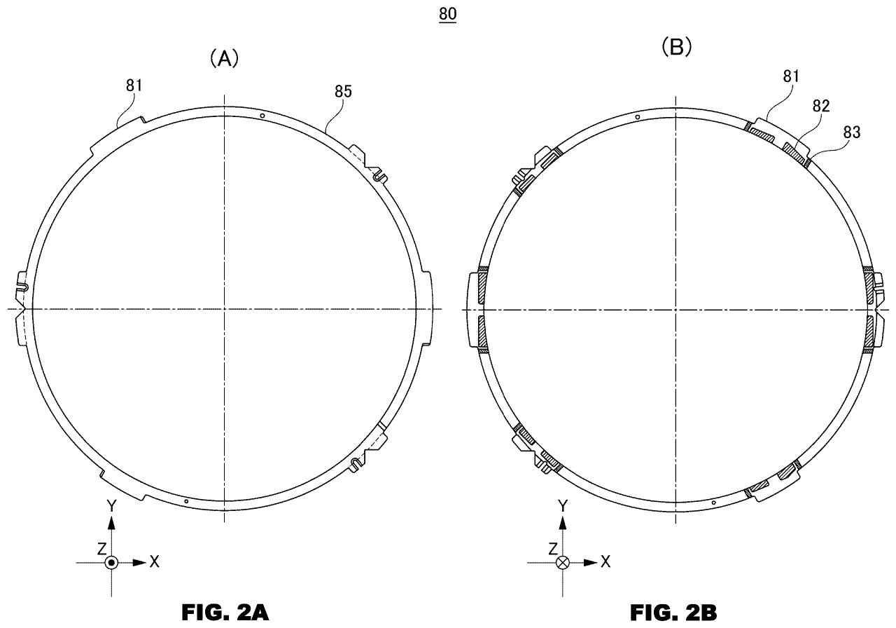

FIG. 2 is an example of a plan view of the locking ring member, and FIG. 2A shows a first surface (upper surface), while FIG. 2B shows a second surface (lower surface).

The probe substrate 32 is mounted on the prober 12 by mounting the locking ring member 80 on the upper surface of the edge part of the probe substrate 32 (the substrate member 321), and then fixing the probe substrate 32 with the locking ring member 80 mounted, to the card holder 28 mounted on the prober 12.

The locking ring member 80 is a mounting member used to mount the probe substrate 32 on the card holder 28 of the prober 12, and is a ring-shaped member made of stainless steel which is alloy steel containing, for example, iron and chromium.

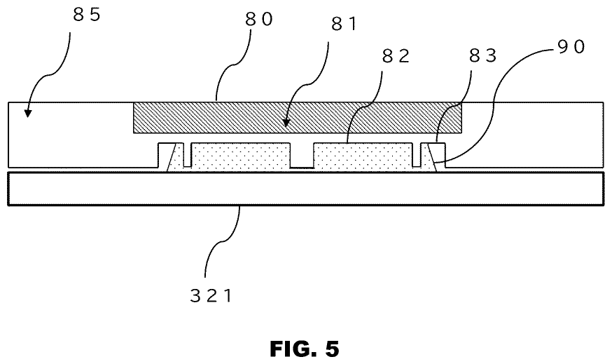

The locking ring member 80 includes a ring shape part 85, and a plurality of ring flanges 81 serving as projection portions, which are the portions protruding outward from the peripheral edge part of the ring shape part 85, arranged apart from each other along the peripheral edge, and having a plurality of adhesive application points arranged apart from each other on the ring shape part 85, for bonding to the substrate member 321. The locking ring member 80 further has, on the second surface side (lower surface) where the ring flanges 81 are arranged, a plurality (two in the present embodiment) of adhesive application recesses 82 serving as concave portions where an adhesive 90 is applied (FIG. 5), and a plurality (two in the present embodiment) of flow-stop recesses 83 serving as flow-stop concave portions where the adhesive 90 flowing out from the adhesive application recesses 82 is stopped (retained).

As shown in FIG. 5, the adhesive 90 bonds the second surface (lower surface) of the locking ring member 80 to the substrate member 321 (first surface). FIG. 5 shows the state in which the adhesive 90 having flowed out from the adhesive application recesses 82 flows and is retained in the flow-stop recesses 83.

In order to clearly show the state in which the adhesive 90 flows in the flow-stop recesses 83 in FIG. 5, a gap appears to exist between the locking ring member 80 and the substrate member 321. However, in reality, the adhesive 90 bonds the locking ring member 80 to the substrate member 321 such that substantially no gap is formed therebetween.

In the present embodiment, an adhesive, which has a low elastic modulus (for example, in the range from several Mpa to several thousand Mpa) and high bonding strength (for example, at least several tens of N/mm²) even in high temperature environments, is assumed to be used as the adhesive 90. Accordingly, even in high-temperature environments of, for example, 125° C. or higher, or even in the environments where the temperature varies from a low of minus 20° C. to a high of 150° C., the adhesive 90 is able to maintain the bonding state of the substrate member 321 and the locking ring member 80, without detaching.

The adhesive 90 has a lower elastic modulus in comparison with that of a conventional adhesive, and the thermal expansion coefficient of the substrate member 321 (ceramic) is different from the thermal expansion coefficient of the locking ring member 80 (metal). This generates large stress on the ceramic substrate member 321 due to the difference in thermal expansion generated as the temperature varies.

In the present embodiment, in view of the fact that the expansion and contraction amount of an object increases in proportion to the outer shape size, the problem of the adhesive 90 having a low elastic modulus is solved by bonding a part (the flow-stop recesses 83) of the locking ring member 80 to the substrate member 321 (by bonding them partially).

### A-3. Method of Mounting Locking Ring Member on Probe Substrate

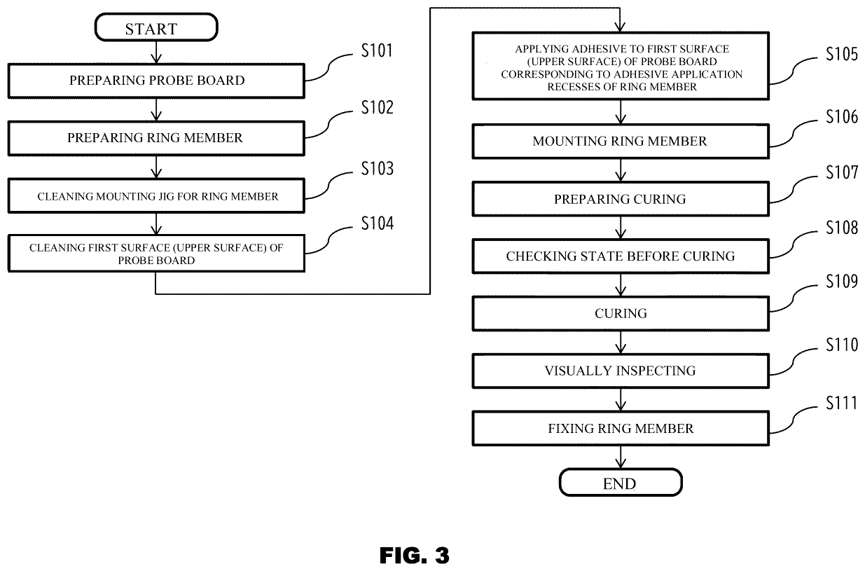

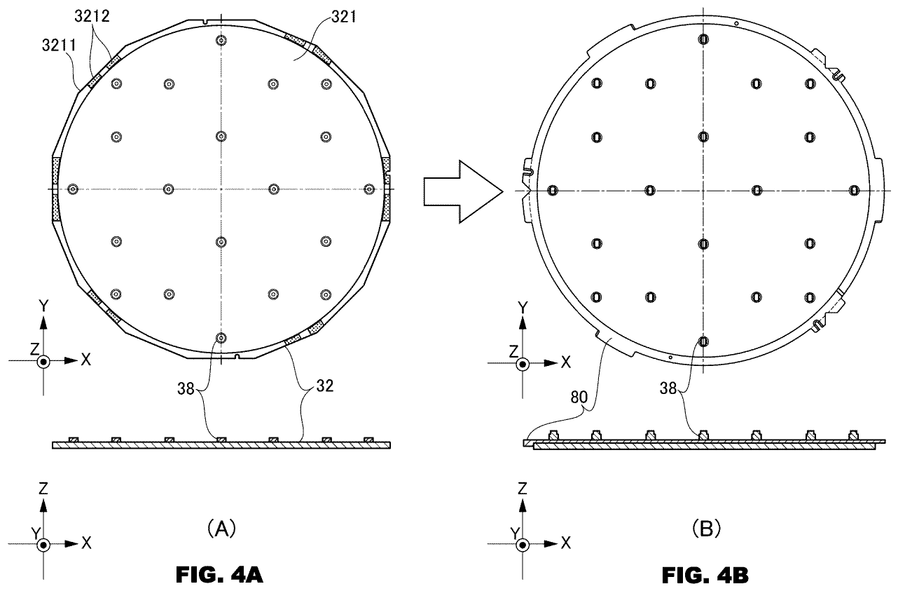

FIG. 3 is a flowchart indicating a method of mounting the locking ring member 80 on the probe substrate 32 according to the embodiment. FIG. 4A shows the front view and the side view of the components of the probe substrate 32 before the mounting of the locking ring member, and FIG. 4B shows the front view and the side view of the probe substrate 32 after the mounting of the locking ring member. As shown in FIG. 4A, the plurality of anchors 38 are provided to support gap holding members for holding the gap between the wiring circuit substrate 58 and the probe substrate 32, on the first surface (for example, upper surface) which is made of ceramic, of the substrate member 321 of the probe substrate 32.

The method of mounting the locking ring member 80 on the substrate member 321 of the probe substrate is described below with reference to FIG. 3 to FIG. 5.

In FIG. 3, the method includes first preparing the substrate member 321 of a ceramic substrate (in step S101), and further preparing the locking ring member 80 (in step S102), to set the substrate member 321 and the locking ring member 80.

The method includes cleaning a mounting jig for mounting the locking ring member 80 (in step S103). The method includes cleaning the first surface (for example, upper surface) of the substrate member 321 of a ceramic substrate (in step S104).

The method includes applying the adhesive 90 to an edge part 3211 (six bonding points 3212) of the first surface (upper surface) of the probe substrate corresponding to the adhesive application recesses 82 of the second surface (lower surface) of the locking ring member 80 in order to mount the locking ring member 80 on the edge part 3211 of the substrate member 321 (in step S105), and mounting the locking ring member 80 on the edge part 3211 of the substrate member 321 (in step S106).

The method includes preparing curing of the adhesive 90 in order to secure the bonding between the substrate member 321 made of ceramic and the locking ring member 80 made of stainless steel (in step S107).

The method includes visually checking the state of the substrate member 321 and the locking ring member 80 before the curing of the adhesive 90 (in step S108). The method further includes curing the adhesive 90 by heating in the state where the locking ring member 80 is mounted on the edge part 3211 of the substrate member 321 (in step S109).

The method includes, after the curing, visually inspecting the states of the probe substrate 32 and the locking ring member 80 (in step S110), and fixing the locking ring member 80 if there are no defects (in step S111), so that the locking ring member is mounted on the probe substrate 32. The locking ring member 80 and the substrate member 321 may be fixed to each other using several fixing elements such as screws or bolts, in addition to the adhesive 90.

### A-4. Effects of Embodiment

As described above, the present embodiment provides the following effects.

The locking ring member 80 is mounted on the probe substrate 32 by the method of applying a high-temperature-resistant, high-strength adhesive (the adhesive 90) to only the plurality of adhesive application recesses 82 arranged apart from each other, thereby partially bonding the locking ring member 80 to the substrate member 321 (ceramic), instead of application to the entire periphery of the ring shape part 85 of the locking ring member 80. This reduces the area affected by the difference in thermal expansion and suppresses the generation of stress, thereby preventing the damage of the substrate member 321.

As a result, the present embodiment provides higher durability of the bonding part between the probe substrate 32 and the locking ring member 80, and allows for a longer service life.

### B. Other Embodiments

Some modifications according to the present disclosure have been described in the above description of the embodiment, and the present disclosure is further applicable to other embodiments described below.

### B-1

In the embodiment described above, the two adhesive application recesses 82 are arranged in each of the areas of the ring flanges 81 on the lower surface of the ring shape part 85 of the locking ring member 80. The number of the adhesive application recesses 82 is not limited to a specific number. In other words, the number of the adhesive application recesses 82 may be one, or three or more.

### B-2

The shapes (including groove cutting, area, and the like) of the adhesive application recesses 82 are not limited to a specific shape. For example, the shapes of the adhesive application recesses 82 may be square, round, triangle, and circle (including oval). These shapes may be dots, in view of the purpose of bonding in small patches.

### B-3

In the embodiment described above, the two adhesive application recesses 82 (concave and convex portions) are arranged in each of the areas of the ring flanges 81 of the ring shape part 85 of the locking ring member 80. Alternatively, the concave and convex portions (by machining) for application of adhesive may be arranged on the substrate member 321, or both the ring shape part 85 of the locking ring member 80 and the substrate member 321. The adhesive is not applied on the lower surfaces of the ring flanges 81 because the surfaces are subjected to the contacting and mounting with respect to the card holder 28.

### B-4

In the embodiment described above, the flow-stop recesses 83 are arranged on the both sides of the adhesive application recesses 82 in the ring shape part 85 of the locking ring member 80. In a modification, the flow-stop recess 83 may not be arranged.

### B-5

In the embodiment described above, only one type of adhesive (high-temperature-resistant, high-strength adhesive) is used to bond the locking ring member 80 to the substrate member 321. Alternatively, two or more types of adhesives may be used.

For example, a conventional adhesive (high-elasticity adhesive) may be used at a point outside the areas of the ring flanges 81 of the locking ring member 80.

### REFERENCE SIGNS LIST

10 TEST APPARATUS
12 PROBER
14 TEST HEAD
18 TEST STAGE
20 CHUCK
24 PLACEMENT SURFACE
26 DEVICE UNDER TEST
28 CARD HOLDER
30 PROBE
32 PROBE SUBSTRATE
34 INTERPOSER
38 ANCHOR
40 CONNECTION TERMINAL
58 WIRING CIRCUIT SUBSTRATE
60 CONNECTION CABLE
80 LOCKING RING MEMBER
81 RING FLANGE
82 ADHESIVE APPLICATION RECESS
83 FLOW-STOP RECESS
85 RING SHAPE PART
90 ADHESIVE
321 SUBSTRATE MEMBER
3211 EDGE PART
3212 BONDING POINT

1. A locking ring member having a plate shape, the locking ring member used to mount a probe substrate on a top plate of a prober included in a test apparatus used to test a device under test, the locking ring member comprising:
a ring shape part; and
projection portions protruding outward from a peripheral edge part of the ring shape part, the projection portions arranged apart from each other along the peripheral edge part, wherein
the ring shape part included in the locking ring member has one surface facing the probe substrate, and another surface opposite to the one surface,
an adhesive applied at a plurality of points separately from each other bonds the one surface facing the probe substrate of the ring shape part included in the locking ring member to one surface of the probe substrate, and
the ring shape part included in the locking ring member has a concave portion in each of a plurality of points subjected to application of the adhesive.

2. The locking ring member according to claim 1, wherein
the ring shape part included in the locking ring member has at least one concave portion subjected to the application of the adhesive in areas of the plurality of projection portions protruding outward from the peripheral edge part.

3. The locking ring member according to claim 2, wherein
the ring shape part included in the locking ring member has at least one flow-stop concave portion for stopping the adhesive flowing out from the concave portion.

4. The locking ring member according to claim 1, wherein
the probe substrate is made of ceramic, the locking ring member is made of metal, and the adhesive has high bonding strength in environments of 125° C. or higher.

5. The locking ring member according to claim 2, wherein
the probe substrate is made of ceramic, the locking ring member is made of metal, and the adhesive has high bonding strength in environments of 125° C. or higher.

6. The locking ring member according to claim 3, wherein
the probe substrate is made of ceramic, the locking ring member is made of metal, and the adhesive has high bonding strength in environments of 125° C. or higher.
